(19) United States
(12) Patent Application Publication
(10) Pub. No.: US 2015/0363330 A1
(43) Pub. Date: Dec. 17, 2015

(54) Flash NAND device bad page replacement

(71) Applicant: Daniel Robert Watkins, Campbell, CA (US)

(72) Inventor: Daniel Robert Watkins, Campbell, CA (US)

(21) Appl. No.: 14/120,680

(22) Filed: Jun. 17, 2014

(51) Int. Cl. G06F 12/12; G11C 7/10; G11C 15/00; G11C 29/42; G06F 12/02; G11C 29/50

(52) U.S. Cl. CPC G06F 12/121; G06F 12/0246; G11C 29/50004; G11C 15/00; G11C 29/42; G11C 7/1072; G11C 2029/5004; G06F 2212/69; G06F 2212/7209

(57) ABSTRACT

Where one or more flash NAND devices are in an array where bit error recovery resolution is available, the controller can log what pages have had what degree of fails, and program a Replace Bad Page function to replace the bad page with a new page from another new die as needed. The Replace Bad Page function with logic blocks, content addressable memory and RAM, once programmed, provides the means to know when a bad page is being accessed and displaces this access with access to the new page, with no change in overall page access function or performance.

### BACKGROUND OF THE INVENTION

The invention pertains to an access method to flash nand devices using logic and spare flash nand devices, that significantly extends the lifecycle of the overall group of flash nand devices, without affecting function or performance.

### DESCRIPTION

1. Field of the Invention

The invention relates to the field of functional replacement of bad pages, particularly in a nand array system.

2. Prior Art

Typically, nand devices have a mechanism for block replacement in nand devices, such as manufacturing or nand array controller's use of the ‘Invalid Block Map Building Algorithm’. But there is a limited number of redundant blocks manufactured in the die.

Typically, the nand array will support bit error recovery resolution, but this has limitations, such as 50 bits recovered per 2240 byte codeword, where if it goes beyond 50 errors the card may have an uncorrectable error which can be a fatal error (the card would need to be replaced).

The nand array may have parity substitution, where if a nand device has too many errors, it is removed from use and the horizontal width of the nand array is reduced by the bit width of the removed device (typically a byte). This has limitations as the performance can be reduced, the life of the card can be reduced, and this can be done only a number of fixed times (depending on the system tolerance for the reduced bit width).

### SUMMARY OF THE INVENTION

A bad flash nand page replacement methodology and feature is described, without the limitations of block granularity or parity substitution based device removal, and replaces bad bits from pages such that less time is consumed with lengthy error recovery resolution.

Every next process node the Flash NAND devices use, has less write lifecycle time, leading to earlier block fails. The lifecycle of the flash is limiting the lifecycle of the add-on card, which limits the economic value of the add-on card. Further, if the card shipped does not meet the lifecycle goal, it can be returned as an RMA and need to be replaced, which reflects economic loss. Also, if ldpc ecc coding is used, there is degraded performance as the card NAND devices wear out, as ldpc can consume hundreds of iteration cycles to correct corrupt words.

Introduced here is new technology to lengthen the useful lifecycle of NAND add-on cards, called Replace Bad Page (RBP).

The RBP features:
Replaces down to a page granularity, with no noticeable change in performance or function.
When a UECC (uncorrectable ecc) occurs, the controller can decide to replace ‘n’ bad pages, essentially with (dynamic) self-healing. The bad page is made invalid and a replacement page is used, consuming a few cycles. Note with ldpc decoders consuming at times hundreds of iteration cycles to correct corrupt words, adding a few cycles to replace a page is reasonable, actually improving performance since there will be less corrupt words.
It can be integrated with the NAND device or not.
As many spare page sets as needed, can be added.
The controller can establish a threshold for when to replace bad pages (for example, after 4 fails on last 100 accesses to page 4 of a device).
On power-cut, controller can store RBP CAM & SRAM values, to host or to flash.
Page fail grooming can be done, where the controller can do erase/prog/read to all blocks & pages that are valid in flash and select the blocks with the least page fails, leading to the likely longest time before another grooming is needed or another UECC is to occur (this best positions the hardware for the best performance).
optionally, it enables parity substitution on a page boundary.

### BRIEF DESCRIPTION OF THE DRAWINGS

FIG. 1 is a block diagram showing the overall architecture of the RBP and its use in a flash nand device.

FIG. 2 is a block diagram showing the use of the RBP module outside of a flash nand device.

### DETAILED DESCRIPTION OF THE PRESENT INVENTION

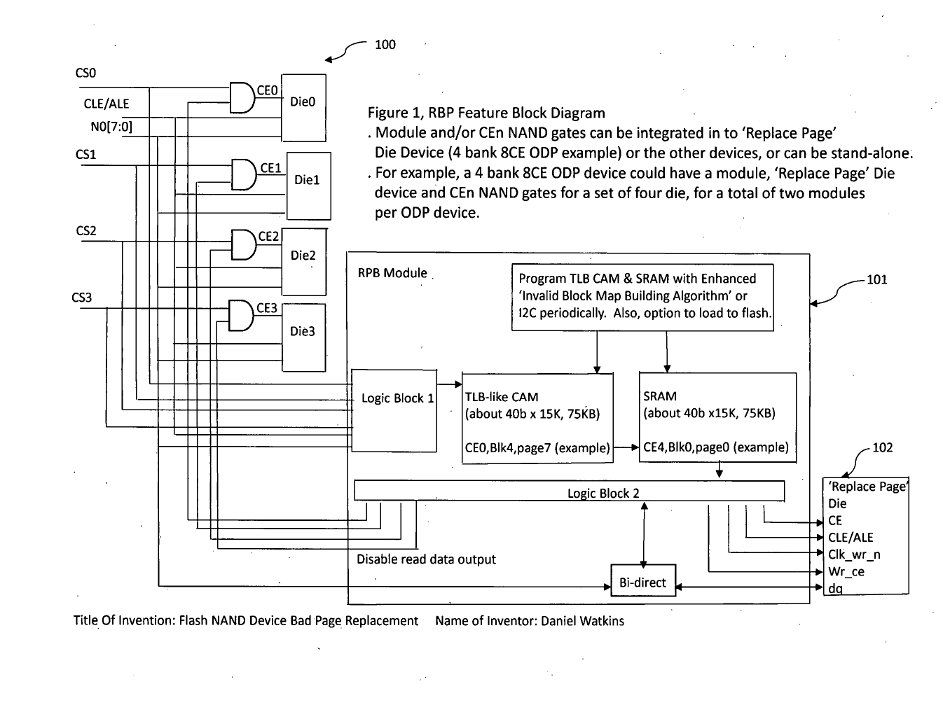

FIG. 1 illustrates a 4 bank 8CE ODP NAND device example, with a RBP module and Replace Page Die added. The embodiments described herein are not limited to this example. Dies with NAND CE 100 include dies 0 through 7, which are in a typical ODP (octal die package) device, as well as NAND gates which are used to prevent the read data output on accesses where the ‘Replace Page’ die is being read instead (as the original die access is now a bad page). RBP Module 101 includes Logic Block1, a TLB-like CAM, an SRAM the CAM output accesses, Logic Block2 and a method to program the TLB CAM & SRAM periodically. Logic Block1 monitors the ODP access, sending what page on what die is being accessed, to the TLB-like CAM. If this access has a match, in the CAM, the CAM sends the match entry information (including CE #, Block # and page #) to the SRAM, where the SRAM outputs a translation (including CE #, Block #, and page #). Logic Block2 uses this SRAM output to sponsor a working page read from the ‘Replace Page’ Die (instead of a read from the original bad page die, which control to the NAND gates will prevent read data output from).

A new entry to the CAM & SRAM is added when a dynamic self-healing event occurs. The programming of the CAM & SRAM can be done by the controller, with an enhanced ‘Invalid Block Map Building Algorithm’ or a I2C interface. The ‘Invalid Block Map Building Algorithm’ is well known in the industry, as it is fundamental in current nand flash technology. Further I2C is a well known industry standard for accesses between chips for programming.

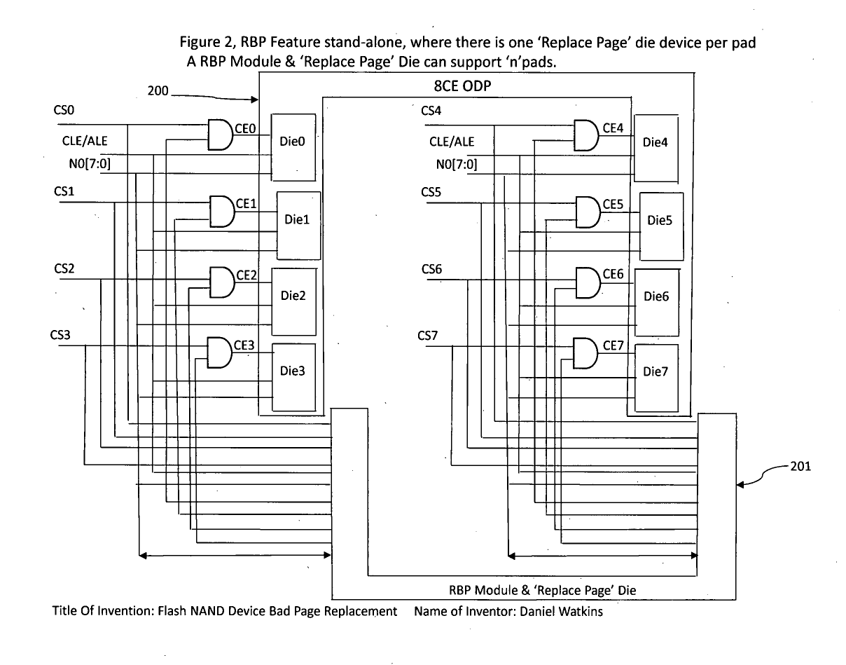

FIG. 2 is the RBP feature where it is not integrated in the NAND device. The embodiments described herein are not limited to this example.

Dies 200 include dies 0 through 7, which are in a typical ODP device. RBP Module 201 includes all that 101 does, plus expanded support for a second set of four die. That is, a bad page on the first set of four die or the second set of four die, would be displaced with a working page from the ‘Replace Page’ die. This illustrates the portability and scalability of the technology, being able to support ‘n’ pads, even external to the nand flash die package. Since many SSD products have the nand controller on the same card as the nand array, this RBP feature logic can be integrated with the controller and Replace Page Dies can be added to the array, on next generation products, making integrating this technology straight forward with no form-fit change.

The Replace Page Dies can be on the NAND array and the rest of the logic can be on the ASIC or FPGA of the controller, or even a PLD. The minimum number of Replace Page Die per nand array is one and the maximum would be the current number in the nand array. Optionally, the Replace Page Die with the RBP feature can be a retrofit of a card that has been in use for some time already. Optionally, implementation could be a daughter card with the Replace Page Die with RBP feature module on it. This could be used to extend the life of cards in the field, costing just some daughter cards with a few more flash nand devices, far less than the replacement cost of the card.

During the lifecycle of the nand array, there are words read that have bit errors, that can typically be corrected by the ECC and/or LDPC error correction technology in use. The controller can log which devices' pages are having these errors. When a device page has errors above a predetermined threshold, the controller can use the RBP feature to swap out this bad page with a new page from the Replace Page Die. The controller does this by adding the bad page address and the new page address in the CAM and RAM respectively (using an enhanced ‘Invalid Block Map Building Algorithm’ or a I2C interface), such that on subsequent accesses to the page, only the new page is used. Only bad pages from the originally accessed devices can be swapped out. Only new pages from the Replace Page Die can be used for swapping. There is no change in function or performance with the used of this new page. The RBP significantly extends the lifecycle and reliability of the NAND add-on card. Further, RMAs are reduced in number. Adding even ⅓ longer lifecycle with this technology would extend the card life from (typically) 3 years to 4 years, enabling the product to be the leader in the market, in terms of reliability.

IHS iSuppli Research in January 2013 states 2014 SSD revenue will be $15 B, growing to $20 B by 2016 (& 239 M units will be shipped). So, if 239 M units in 2016 would be enabled to have ⅓ longer lifecycle with this new technology (from the typical 3 year warranty to 4 year warranty), this would be a value add of $6.6 B. Of course, there is also the existing cards that can be retrofitted with this technology, which could also be a large market. The top 25 SSD companies in 1Q14 are Fusion-io, IBM, LSI, HGST (WD), OCZ, SanDisk, Skyera, violin Memory, Pure Storage, WhipTail, Nimbus Data Systems, Maxta, Micron, A3Cube, Kaminario, Diablo Technologies, Intel, Tegile Systems, Seagate, Samsung, EMC, RunCore, Virtium, Foremay, and Greenliant.

1. A nand flash access means comprising:
(a) Logic block one means, that receives input signals that the other NAND die in the device receive, for providing a word line input that accesses the content addressable memory (CAM), as a duplicate access;
(b) CAM means for providing an address translation, based on preloaded content, via a bus;
(c) RAM means for providing the mapped address, based on preloaded content, accessed by the address translation bus;
(d) Logic block two means, that upon receipt of a valid RAM mapped address output, generates the necessary signaling to control the Replace Die to provide a working access and disable the original access to other NAND die in the device.
(e) Replace Die

2. A nand flash access means according to claim 1 wherein said preloaded content of CAM and RAM is provided by an enhanced version of the pre-existing ‘Invalid Block map Building Algorithm’.

3. A nand flash access means according to claim 1 wherein said preloaded content of CAM and RAM is provided by an industry standard I2C interface.

4. A nand flash access means according to claim 1 wherein said CAM and RAM content is optionally loaded from flash and optionally stored to flash.

5. A nand flash access means according to claim 1 wherein said logic block one processes the input signals to generate an access address to the CAM, where there is then optionally an address match, that is then used to access the RAM, where the RAM will provide the mapped address.

6. A nand flash access means according to claim 1 wherein a NAND flash array memory fail is optionally resolved by updating the CAM and RAM line with the failing die access chip enable & address, and the Replace Page Die chip enable & address, respectively.

7. A nand flash access means according to claim 6 wherein the controller can update one or more CAM and RAM lines, to reflect one or more bad pages being replaced with new pages, on the same transfer.

8. A nand flash access means according to claim 1 wherein the controller can accumulate statistics on what page fails have occurred and set a threshold for when a failing page is to be replaced with a new page.

9. A nand flash access means according to claim 1 wherein a CAM & RAM entry represents a bad page access displaced by a new page access, where if the new page access morphes to a bad page, this bad page can be displaced by another new page with a change to the RAM entry only.

10. A nand flash access means according to claim 1 wherein the two logic blocks, the CAM & RAM functions, and the replacement page dies, scale to the nand array page replacement needs.

11. A nand flash access means according to claim 1 wherein on the nand array power-cut, the controller optionally can store the RBP CAM & SRAM values, to host memory or to flash memory.

12. A nand flash access means according to claim 1 wherein the controller can optionally do fail grooming, where blocks and pages are validated with erase-program-read operations and page fail statistics are reviewed, where then the least likely to fail blocks and pages are placed in to use.

13. A nand flash access means according to claim 1 wherein the controller can optionally do parity substitution on a page boundary.

14. A nand flash access means according to claim 1 wherein the means is integrated with the nand device.

15. A nand flash access means according to claim 1 wherein the means is integrated with the nand array controller.

16. A nand flash access means according to claim 1 wherein the access displaces a bad page entry.

17. A nand flash access means according to claim 1 wherein the access displaces a bad page.

18. A nand flash access means according to claim 1 wherein the access displaces a bad block.

19. A nand flash access means according to claim 1 wherein the access displaces a bad die.

20. A nand flash access means according to claim 1 wherein the access displaces a bad device.

21. A nand flash access means according to claim 1 wherein the access displacing a fail, has no change in function and performance, from the original access.
